(19) United States
(12) Patent Application Publication
(10) Pub. No.: US 2015/0024522 A1
(43) Pub. Date: Jan. 22, 2015

(54) ORGANOMETAL MATERIALS AND PROCESS

(71) Applicant: Rohm and Haas Electronic Materials LLC, Marlborough, MA (US)

(72) Inventors: Deyan WANG, Hudson, MA (US); Peter TREFONAS, III, Medway, MA (US); Kathleen M. O'CONNELL, Cumberland, RI (US); Dominic C. YANG, Gangnam-gu (KR)

(21) Appl. No.: 13/947,128

(22) Filed: Jul. 22, 2013

(51) Int. Cl. H01L 51/52

(52) U.S. Cl. CPC H01L 51/524
USPC 438/26; 524/174; 106/287.19

(57) ABSTRACT

Coating compositions are used to deposit films on electronic device substrates, which films are subjected to conditions that form an oxymetal precursor material layer on a matrix precursor material layer, and then such layers are cured to form a cured oxymetal layer disposed on a cured matrix layer.

The present invention relates generally to the field of solution-borne organometallic compounds, and more particularly to the field of electronic device manufacture using such solution-borne organometallic compounds.

The needs for certain layers having etch selectivity in lithography and layers for blocking both oxygen and moisture in certain semiconductor fabrications, such as organic light emitting diode (OLED) fabrications or photovoltaic devices, have lead to the use of films containing oxymetal domains in the manufacture of electronic devices. Oxymetal layers are generally characterized as films containing a majority of inorganic domains with (—M—O—)ₙ linkages (oxymetal domains), where M is a metal and n>1, and may also be composed of minor amounts of other elements, such as carbon. Oxymetal layers may be composed of mixed domains, such as containing both oxymetal domains and metal nitride domains.

Conventional oxymetal films may contain one or more metals, such as Hf, Zr, Ti, W, Al, Ta and Mo, depending on the particular application. The etch resistance of oxymetal domain-containing films depends, in part, on the particular metal used as well as the level of (—M—O—)ₙ domains present in the film, with an increased level of such domains providing greater etch resistance. Barrier films used in OLED applications conventionally contain Al or Si, that is (—Al—O—)ₙ or (—Si—O—)ₙ domains, respectively, where n>1. Aluminum oxide-containing films are known to have reduced transport of oxygen (O₂), while silicon oxide-containing films are known to have reduced transport of moisture vapor. Any defects in such barrier films, such as pinholes, or any other defect causing incomplete coverage of the lower film presents a possible pathway for gas or vapor to access the lower film.

Oxymetal films, such as alumina and silica films, are conventionally applied by chemical vapor deposition (CVD), onto an electronic device substrate. For example, International Pat. App. WO 2012/103390 discloses a barrier stack having one or more oxide-containing barrier layers, such as aluminum oxide or silicon oxide layers, adjacent to a reactive inorganic layer on a flexible (plastic) substrate for reducing the transport of gas or vapor through the stack. According to this patent application, the reactive inorganic layer functions to react with any gas or vapor that penetrates through the barrier layer. This patent application fails to suggest any suitable materials for forming such barrier layers, and focuses on conventional film deposition techniques, such as vapor deposition techniques.

Spin-on techniques are widely used in electronic device manufacture, including in the deposition of oxymetal films, and offer advantages over conventional vapor deposition methods of depositing films. For example, spin-on techniques can use existing equipment, can be completed within a few minutes, and can provide a uniform coating over a substrate. Conventional spin-on techniques allow for the deposition of a single oxymetal film at one time. Where multiple oxymetal films are used, such as in a barrier stack, each oxymetal film must be separately applied and cured. Conventional spin-on techniques for oxymetal films deposit a solution of an oxymetal precursor on a substrate, followed by baking to remove solvent, and then curing to form the oxymetal film. If such film is not cured before deposition of a second film, the solvent used in the second oxymetal precursor solution may cause intermixing problems with the uncured first oxymetal film. There is a need in the art for a process to provide multiple oxymetal films from a single liquid deposition process directly on an electronic device substrate.

The present invention provides a composition comprising a matrix precursor material, an oxymetal precursor material having a surface energy of 20 to 40 erg/cm², and an organic solvent, wherein the matrix precursor material has a surface energy that is higher than the surface energy of the oxymetal precursor material.

The present invention also provides a method of forming an oxymetal layer on a matrix layer on an electronic device substrate comprising: disposing a layer of a coating composition on an electronic device substrate, wherein the coating composition comprises a matrix precursor material, an oxymetal precursor material having a surface energy of 20 to 40 erg/cm², and an organic solvent; subjecting the coating composition layer to conditions such that a layer of the oxymetal precursor material forms on a layer of the matrix precursor material; and curing the layer of matrix precursor material and the layer of oxymetal precursor material.

As used throughout this specification, the following abbreviations shall have the following meanings, unless the context clearly indicates otherwise: ca.=approximately; ° C.=degrees Celsius; g=grams; mg=milligrams; mmol=millimoles; L=liters; mL=milliliters; μL=microliters; nm=nanometers; A=angstroms; and rpm=revolutions per minute. All amounts are percent by weight (“wt %”) and all ratios are molar ratios, unless otherwise noted. The term “oligomer” refers to dimers, trimers, tetramers and other relatively low molecular weight materials that are capable of further curing. “Alkyl” and “alkoxy” refer to linear, branched and cyclic alkyl and alkoxy, respectively. By the term “curing” is meant any process that polymerizes or otherwise increases, such as by condensation, the molecular weight of a material or layer. The terms “film” and “layer” are under interchangeably through this specification. The articles “a”, “an” and “the” refer to the singular and the plural. All numerical ranges are inclusive and combinable in any order, except where it is clear that such numerical ranges are constrained to add up to 100%.

The coating compositions useful in the present invention comprise a matrix precursor material, an oxymetal precursor material having a surface energy of 20 to 40 erg/cm², and an organic solvent, wherein the matrix precursor material has a surface energy that is higher than the surface energy of the oxymetal precursor material. A wide variety of matrix precursor materials may suitably be used, such as, without limitation, polymeric materials, silicon-containing materials, organometallic materials, or a combination thereof, provided that such matrix precursor materials are capable of being cured, have a surface energy higher than the surface energy of the oxymetal precursor material used, are soluble in the organic solvent used, are stable under conditions used to dispose a layer of the coating compositions on a substrate, and when cured have sufficient thermal stability to withstand the curing temperature of the oxymetal precursor material. Depending on the particular oxymetal precursor material and the particular use of the present invention, the curing temperature of the oxymetal precursor material could be in the range of 250 to 400° C. for a period of up to 60 minutes or greater. For certain applications, such as oxygen or moisture barrier films, the matrix precursor material should provide a cured matrix having a relatively dense film morphology and having relatively less polar and hydrophilic functional groups. It is preferred that the matrix precursor material is chosen from polymeric materials and silicon-containing materials, and more preferably the matrix precursor material is a silicon-containing material. The matrix precursor material used in the present coating compositions has a surface energy that is higher then the surface energy of the oxymetal precursor material. Preferably, the matrix precursor material has a surface energy that is ≧10 ergs/cm² higher than the surface energy of the oxymetal precursor material used, and more preferably has a surface energy that is ≧15 ergs/cm² higher.

Exemplary polymeric matrix precursor materials useful in the present invention include, without limitation: polyarylene materials such as polyphenylene materials and arylcyclobutene-based materials, such as those available under the SiLK™ and CYCLOTENE™ brands, respectively, both available from The Dow Chemical Company. It will be appreciated by those skilled in the art that various other polymeric matrix materials may suitably be used as matrix precursor materials in the present invention. Such polymeric materials may be commercially available, or may be prepared by various known methods.

Exemplary silicon-containing matrix precursor materials include, without limitation, siloxane materials and silsesquioxane materials, and preferably silsesquioxanes. Siloxane materials have the general formula (R₂SiO₂)ₙ and silsesquioxane materials have the general formula (RSiO_{3/2})ₙ, where R is typically selected from OH, C₁₋₄alkoxyl, C₁₋₄alkyl and C₆₋₁₀aryl, and wherein the R substituents on at least one Si are selected from C₁₋₄alkyl and C₆₋₁₀aryl. Suitable silsesquioxanes are typically prepared by a condensation reaction between one or more organotrialkoxysilanes, which typically have the formula RSi(OR)₃, where each R is independently selected from C₁₋₄alkyl and C₆₋₁₀aryl. Such silicon-containing materials are generally commercially available, such as from Dow Corning, Midland Mich., or may be prepared by various methods known the art, such as that disclosed in U.S. Pat. No. 6,271,273 (You et al.). Such silicon-containing materials include silicon-metal hybrid materials such as silicon-titanium hybrid materials and silicon-zirconium hybrid materials.

A wide variety of organometallic materials may be used as the matrix precursor material. Suitable organometallic materials are film-forming and are typically polymeric (such as oligomeric), but may also be non-polymeric, and may contain a single metal, or may contain two or more different metals. That is, a single organometallic material, such as an oligomer, may have only one metal species, or may contain 2 or more different metal species. Alternatively, a mixture of organometallic materials, each material having a single metal species, may be employed in order to deposit a mixed metal film. It is preferred that an organometallic material contain one or more atoms of a single metal species, and not different metal species. Suitable metals useful in the present organometallic materials are any metal in Groups 3-14 of the periodic table. Preferably, the metal is chosen from Groups 4, 5, 6 and 13, and more preferably from Groups 4, 5 and 6. Preferred metals include titanium, zirconium, hafnium, tungsten, tantalum, molybdenum, and aluminum, and more preferably titanium, zirconium, hafnium, tungsten, tantalum, and molybdenum.

One suitable class of organometallic materials for use in the present compositions is a metal-oxygen oligomer of formula (1)

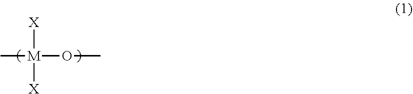

where each X is independently selected from light attenuating moieties, diketones, C₂₋₂₀polyols and C₁₋₂₀alkoxides; and M is a Group 3 to Group 14 metal. Preferred X substituents are diketones and C₁₋₂₀alkoxides, and more preferably diketones and C₁₋₁₀alkoxides. In one embodiment it is preferred that at least one X is a diketone of the structure

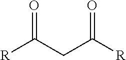

where each R is independently chosen from: hydrogen; C₁₋₁₂alkyl, C₆₋₂₀aryl, C₁₋₁₂alkoxy, and C₆₋₁₀phenoxy, and more preferably both X substituents are diketones. More preferably, each R is independently chosen from C₁₋₁₀alkyl, C₆₋₂₀aryl, C₁₋₁₀alkoxy, and C₆₋₁₀phenoxy. Exemplary groups for R include methyl, ethyl, propyl, butyl, pentyl, hexyl, benzyl, phenethyl, naphthyl; phenoxy, methylphenoxy, dimethylphenoxy, ethylphenoxy and phenyloxy-methyl. A preferred structure of the metal-oxygen oligomer has formula (1a)

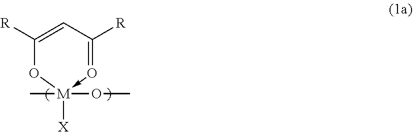

where M, X and R are as described above. Such metal-oxygen oligomers are disclosed in U.S. Pat. No. 7,364,832. Similar metal-oxygen oligomers which are also useful in the present invention are found in U.S. Pat. Nos. 6,303,270; 6,740,469; and 7,457,507, and in U.S. Pat. App. Pub. No. 2012/0223418.

Another suitable class of organometallic materials useful in the present invention is an oligomer comprising one or more metal-containing pendant groups. Preferably, the organo-metal oligomer comprising one or more metal-containing pendant groups comprises, as polymerized units, one or more (meth)acrylate monomers, and more preferably one or more metal-containing (meth)acrylate monomers. Even more preferably, the organo-metal oligomer comprising one or more metal-containing pendant groups comprises as polymerized units one or more monomers of formula (2)

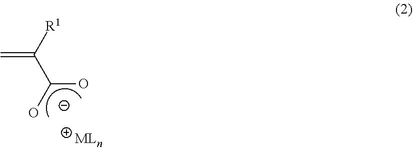

where R¹=H or CH₃; M=a Group 3 to Group 14 metal; L is a ligand; and n refers to the number of ligands and is an integer from 1-4. Preferably, M is a metal chosen from Groups 4, 5, 6 and 13, and more preferably from Group 4, 5 and 6. It is preferred that M=titanium, zirconium, hafnium, tungsten, tantalum, molybdenum, and aluminum, more preferably titanium, zirconium, hafnium, tungsten, tantalum, and molybdenum, and still more preferably zirconium, hafnium, tungsten, and tantalum.

The ligands, L, in formula (2) may be any suitable ligand, provided that such ligands can be cleaved during the curing step to form the metal oxide containing hardmask. Preferably, the ligand comprises an oxygen or sulfur atom bound to, coordinated to, or otherwise interacting with the metal. Exemplary classes of ligands are those containing one or more of the following groups: alcohols, thiols, ketones, thiones, and imines, and preferably alcohols, thiols, ketones, and thiones. Preferably, L is chosen from one or more of C₁₋₆alkoxy, beta-diketonates, beta-hydroxyketonates, beta-ketoesters, beta-diketiminates, amindinates, guanidinates, and beta-hydroxyimines. It is more preferred that L is chosen from one or more of C₁₋₆alkoxy, beta-diketonates, beta-hydroxyketones, and beta-ketoesters, and yet more preferably L is chosen from C₁₋₆alkoxy. The number of ligands is referred to in formula (2) by “n”, which is an integer from 1-4, preferably from 2-4, and more preferably from 3-4. Preferred monomers of formula (2) are Zr(C₁₋₄alkoxy)₃ acrylate, Zr(C₁₋₄alkoxy)₃ methacrylate, Hf(C₁₋₄alkoxy)₃ acrylate, Hf(C₁₋₄alkoxy)₃ methacrylate, Ti(C₁₋₄alkoxy)₃ acrylate, Ti(C₁₋₄alkoxy)₃ methacrylate, Ta(C₁₋₄alkoxy)₄ acrylate, Ta(C₁₋₄alkoxy)₄ methacrylate, Mo(C₁₋₄alkoxy)₄ acrylate, Mo(C₁₋₄alkoxy)₄ methacrylate, W(C₁₋₄alkoxy)₄ acrylate, and W(C₁₋₄alkoxy)₄ methacrylate. The organo-metal compounds of formula (2) can be prepared by a variety of methods, such as by reacting a metal tetraalkoxide with acrylic or methacrylic acid in a suitable solvent, such as acetone.

The organo-metal oligomer comprising one or more metal-containing pendant groups may be comprised of polymerized units of a single monomer (homopolymer) or polymerized units of a mixture of 2 or more monomers (copolymer). Suitable copolymers may be prepared by conventional methods by polymerizing one or more monomers comprising a metal-containing pendant group with one or more other monomers, such other monomers may optionally comprise a metal-containing pendant group, such as is disclosed in U.S. patent application Ser. No. 13/624,946. Suitable ethylenically unsaturated monomers include, without limitation, alkyl(meth)acrylate monomers, aryl(meth)acrylate monomers, hydroxyalkyl(meth)acrylate monomers, alkenyl(meth)acrylates, (meth)acrylic acid, and vinyl aromatic monomers such as styrene and substituted styrene monomers. Preferably, the ethylenically unsaturated monomers are chosen from C₁₋₁₂alkyl(meth)acrylate monomers and hydroxy(C₁₋₁₂)alkyl(meth)acrylate monomers, and more preferably C₁₋₁₂alkyl(meth)acrylate monomers and hydroxy(C₂₋₆)alkyl(meth)acrylate monomers. Such copolymers may be random, alternating or block copolymers. These organo-metal oligomers may be composed of, as polymerized units, 1, 2, 3, 4 or more ethylenically unsaturated monomers in addition to the monomer comprising the metal-containing pendant group, such as a metal-containing (meth)acrylate monomer.

A further class of organometallic materials suitable for use as a matrix precursor material in the present coating compositions is a compound of formula (3)

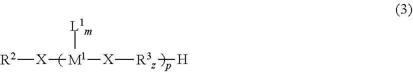

where R²=C₁₋₆alkyl; M¹ is a Group 3 to Group 14 metal; R³=C₂₋₆alkylene-X— or C₂₋₆alkylidene-X—; each X is independently chosen from O and S; z is an integer from 1-5; L¹ is a ligand; m refers to the number of ligands and is an integer from 1-4; and p=an integer from 2 to 25. It is preferred that R² is C₂₋₆alkyl, and more preferably C₂₋₄alkyl. Preferably, M¹ is a metal chosen from Groups 4, 5, 6 and 13, and more preferably from Groups 4, 5 and 6. It is preferred that M¹=titanium, zirconium, hafnium, tungsten, tantalum, molybdenum, and aluminum, more preferably titanium, zirconium, hafnium, tungsten, tantalum, and molybdenum, and still more preferably titanium, zirconium, hafnium, tungsten, and tantalum. X is preferably O. It is preferred that R³ is chosen from C₂₋₄alkylene-X— and C₂₋₄alkylidene-X—, and more preferably from C₂₋₄alkylene-O— and C₂₋₄alkylidene-O—. Preferably, p=5-20, and more preferably 8-15. It is preferred that z=1-4, and more preferably z=1-3.

The ligands, L¹, in formula (3) may be any suitable ligand, provided that such ligands can be cleaved during the curing step to form the metal oxide containing hardmask. Preferably, the ligand comprises an oxygen or sulfur atom bound to, coordinated to, or otherwise interacting with the metal. Exemplary classes of ligands are those containing one or more of the following groups: alcohols, thiols, ketones, thiones, and imines, and preferably alcohols, thiols, ketones, and thiones. Preferably, L¹ is chosen from one or more of C₁₋₆alkoxy, beta-diketonates, beta-hydroxyketonates, beta-ketoesters, beta-diketiminates, amidinates, guanidinates, and beta-hydroxyimines. It is more preferred that L¹ is chosen from one or more of C₁₋₆alkoxy, beta-diketonates, beta-hydroxyketonates, and beta-ketoesters, and yet more preferably L¹ is chosen from beta-diketonates, beta-hydroxyketonates, and beta-ketoesters. The number of ligands is referred to in formula (3) by “m,” which may be from 1-4, and preferably from 2-4. Preferred ligands for L¹ include: benzoylacetonate; pentane-2,4-dionate (acetoacetate); hexafluoroacetoacetate; 2,2,6,6-tetramethylheptane-3,5-dionate; and ethyl-3-oxobutanoate (ethylacetoacetate). Oligomers of formula (3) may be prepared by conventional means known in the art, such as is disclosed in U.S. patent application Ser. No. 13/624,946.

A variety of non-polymeric organometallic materials may be used as matrix precursor materials in the present coating compositions, provided that such compounds are capable of forming a film under the conditions used. Suitable non-polymeric organometallic materials may be homoleptic or heteroleptic (that is, contains different ligands) and include, without limitation metal ketonates, metal ketiminates, metal amidinates, and the like. Exemplary non-polymeric organo-metal compounds include, but are not limited to: hafnium 2,4-pentanedionate; hafnium di-n-butoxide (bis-2,4-pentanedionate); hafnium tetramethylheptanedionate; hafnium trifluoropentanedionate; titanium allylacetoacetonate tris-iso-propoxide; titanium di-n-butoxide (bis-2,4-pentanedionate); titanium di-iso-propoxide (bis-2,4-pentanedionate); titanium di-iso-propoxide(bis-tetramethylheptanedionate); tantalum (V) tetraethoxide 2,4-pentanedionate; zirconium di-n-butoxide (bis-2,4-pentanedionate; zirconium di-iso-propoxide (bis-2,4-pentanedionate); zirconium dimethacrylate di-n-butoxide; zirconium tetramethacrylate; zirconium hexafluoropentanedionate; zirconium tetra-2,4-pentanedionate; zirconium 2,2,6,6-tetramethyl-3,5-heptanedionate; and zirconium trifluoropentanedionate. Such non-polymeric organometallic materials are generally commercially available or may be prepared by a variety of known methods.

It will be appreciated by those skilled in the art that more than one organometallic material may be used as the matrix precursor materials in the present coating compositions. When combinations of organometallic materials are used, such materials may be used in varying amounts, such as from 99:1 to 1:99 by weight, and preferably from 90:10 to 10:90 by weight. Preferably, combinations of organometallic materials are not used.

A wide variety of oxymetal precursor materials may suitably be used in the present coating compositions, provided that such oxymetal precursor materials are capable of forming a film, capable of being cured, have a (static) surface energy of 20 to 40 erg/cm², and are soluble in the organic solvent used. Preferably, the oxymetal precursor materials have a (static) surface energy in the range of 20 to 35 erg/cm², and more preferably 20 to 30 erg/cm². The oxymetal precursor materials of the present invention are different from the matrix precursor materials.

Suitable oxymetal precursor materials comprise a metal chosen from Group 3 to 14 and have at least one low surface energy ligand, that is, a relatively more hydrophobic ligand. Preferably, the oxymetal precursor materials comprise a metal chosen from titanium, zirconium, hafnium, tungsten, tantalum, molybdenum, and aluminum. Low surface energy ligands have more fatty (or hydrocarbyl) character as compared to other ligands used in the oxymetal precursor materials or as compared to the matrix precursor materials. It is believed that a branched or cyclic alkyl moiety is relatively more hydrophobic than the corresponding linear alkyl moiety, and that increasing the branching or cyclic nature of such a moiety helps lower the surface energy of the ligand, and consequently of the oxymetal precursor material. Likewise, alkyl and aryl moieties of increasing carbon chain length also lower the surface energy of the ligand. The present low surface energy ligands comprise one or more C₄₋₂₀hydrocarbyl moieties. Suitable hydrocarbyl moieties include aliphatic hydrocarbyl moieties and aromatic hydrocarbyl moieties. The hydrocarbyl moieties may optionally be substituted with fluorine, where one or more of the hydrogens in the hydrocarbyl moiety are replace with a corresponding number of fluorines. Preferred hydrocarbyl moieties are C₄₋₂₀alkyl and C₆₋₂₀aryl, each of which may be optionally substituted with fluorine. Such C₄₋₂₀hydrocarbyl moiety may be linear, branched or cyclic. C₆₋₂₀aryl moieties include C₆₋₂₀aralkyl moieties and C₆₋₂₀alkaryl moieties, such as benzyl, phenethyl, tolyl, xylyl, ethylphenyl, styryl, and the like. When the low surface energy ligand comprises a C₄₋₆alkyl moiety, such alkyl moiety is preferably branched or cyclic. Preferably, the low surface energy ligand comprises one or more C₆₋₂₀hydrocarbyl moieties, more preferably one or more C₆₋₁₆hydrocarbyl moieties, even more preferably one or more C₈₋₁₆hydrocarbyl moieties, and still more preferably one or more C₁₀₋₁₆hydrocarbyl moieties. Preferred compounds useful in forming low surface energy ligands in the present oxymetal precursor materials are alcohols having a C₄₋₂₀hydrocarbyl moiety and carboxylic acids having a C₄₋₂₀hydrocarbyl moiety. When a carboxylic acid-containing compound is used to form the low surface energy ligand, it is preferred that the carboxylic acid-containing compound have a single carboxylic acid functionality. Compounds having multiple carboxylic acid functionalities tend to form gels which are not suitable for the present coating compositions.

The oxymetal precursor materials useful in the present coating compositions may be monomeric or oligomeric, and preferably are oligomeric. Preferred oxymetal precursor materials are those of the general formula (4)

M^{+m}_{z}O_{z-1}L¹ₓ₂L²_{y2} (4)

wherein M is a Group 3 to 14 metal; L¹ is selected from (C₁-C₆)alkoxy, (C₁-C₃)carboxyalkyl, and (C₅-C₂₀)β-diketonate; L² is a low surface energy ligand comprising a C₄₋₂₀hydrocarbyl moiety; m is the valence of M; z is an integer from 1 to 50; x2 is an integer from 0 to (m(z)−2(z−1)−1); y2 is an integer from 1 to (m(z)−2(z−1)); and x2+y2=m(z)−2(z−1). Preferably, m=3 or 4. It is preferred that z=1 to 30, more preferably 1 to 25, still more preferably 1 to 20, yet more preferably 3 to 25, and even more preferably 3 to 15. Preferably, L²=O—C₄₋₂₀hydrocarbyl or OC(O)—C₄₋₂₀hydrocarbyl, more preferably L²=O—C₆₋₂₀hydrocarbyl or OC(O)—C₆₋₂₀hydrocarbyl, and yet more preferably L²=O—C₆₋₁₆hydrocarbyl or OC(O)—C₆₋₁₆hydrocarbyl. The (C₄-C₂₀)hydrocarbyl moiety of L² optionally comprises one or more substituents selected from the group consisting of hydroxyl, carboxylic acid, (C₁-C₆)alkyl carboxylate and fluoro, preferably (C₁-C₆)alkyl carboxylate and fluoro, and more preferably (C₁-C₄)alkyl carboxylate and fluoro. Suitable low surface energy ligands (L²) include, without limitation: hexanoate, heptanoate, octanoate, nonanoate, decanoate, dodecanoate, cyclohexanoate, benzoate, methylbenzoate, naphthanoate, phenoxy, benzyloxy, t-butoxy, and cyclohexyloxy. For certain applications, not all of the L¹ ligands need to be replaced with L² ligands in order to provide an oxymetal precursor material having a sufficiently low surface energy. In certain embodiments, it is preferred that the amount of L² ligands be from 25 to 100%, more preferably from 25 to 95%, still more preferably from 30 to 95%, and yet more preferably from 35 to 90%, based on the total number of ligands. The percentage of L² ligands can be calculated according to the equation y2/(x2+y2)×100, where x2 and y2 refer to the number of L¹ and L² ligands, respectively.

The present oxymetal precursor materials may be prepared by a variety of procedures known in the art, and are typically prepared by a ligand exchange reaction between a starting metal compound of the formula M^{+m}Xₘ, where X is a ligand to be exchanged, such as (C₁-C₆)alkoxy or (C₅-C₂₀)β-diketonate, and a suitable low surface energy ligand, such as HL² or an alkali or alkaline earth salt thereof such as K⁺⁻L2, where L² is as defined above. Preferably, the low surface energy ligand used in the ligand exchange reaction has the formula HL². In a general procedure, the starting metal compound is combined with the low surface energy ligand and a suitable organic solvent in a flask. The mixture is then heated, typically from room temperature to 80° C. or higher, for a period of time to allow the desired ligand exchange to occur. Following this procedure, 1, 2 or all 3 of the (C₁-C₆)alkoxy or (C₅-C₂₀)β-diketonate ligands on the starting metal compound may be exchanged with a corresponding number of low surface energy ligands. It will be appreciated by those skilled in the art that the number of (C₁-C₆)alkoxy or (C₅-C₂₀)β-diketonate ligands replaced will depend on the steric hindrance of the particular (C₁-C₆)alkoxy or (C₅-C₂₀)β-diketonate ligand, the steric hindrance of the particular low surface energy ligand used, and the length of time the mixture is heated, with increasing length of time providing for greater ligand exchange.

The present coating compositions also comprise one or more organic solvents. A wide variety of organic solvents may suitably be used, provided that the matrix precursor material and the oxymetal precursor material are soluble in the solvent or mixture of solvents selected. Such solvents include, but are not limited to, aromatic hydrocarbons, aliphatic hydrocarbons, alcohols, lactones, esters, glycols, glycol ethers, and mixtures thereof. Exemplary organic solvents include, without limitation, toluene, xylene, mesitylene, alkylnaphthalenes, 2-methyl-1-butanol, 4-methyl-2-pentanol, gamma-butyrolactone, ethyl lactate, 2-hydroxyisobutyric acid methyl ester, propylene glycol methyl ether acetate, and propylene glycol methyl ether. In a preferred embodiment, a solvent system comprising a majority of a first solvent and a minority of a second solvent is used. More preferably, the first solvent has a relatively low surface energy and the second solvent has a relatively higher boiling point than the first solvent, and where the second solvent has a higher surface energy (tension) than the surface energy of the oxymetal precursor material. Exemplary second solvents include, but are not limited to, gamma-butyrolactone, gamma-valerolactone, dipropyleneglycol methyl ether, benzyl benzoate, and the like. Typically, when a solvent mixture is used, the amount of the second solvent is present in an amount of 0.1 to 10 wt %, based on the total weight of the solvent system, with the remainder being the weight of the first solvent. Preferably, the organic solvents contain <10,000 ppm of water, more preferably <5000 ppm water, and even more preferably ≦500 ppm water. It is preferred that the organic solvents do not have free carboxylic acid groups or sulfonic acid groups.

Coating compositions of the present invention may optionally comprise one or more additives, such as curing catalysts, antioxidants, dyes, contrast agents, binder polymers, and the like. Depending on the application, it may be desirable to add one or more curing catalysts to the present compositions to aid in the curing of the matrix precursor material and/or the oxymetal precursor material. Exemplary curing catalysts include thermal acid generators (TAGs) and photoacid generators (PAGs) TAGs and their use are well-known in the art. Examples of TAGs include those sold by King Industries, Norwalk, Conn., USA under NACURE™, CDX™ and K-PURE™ names. Photoacid generators (PAGs) and their use are well-known in the art and are activated upon exposure to a suitable wavelength of light or upon exposure to a beam of electrons (e-beam) to generate an acid. Suitable PAGs are available from a variety of sources, such as from BASF (Ludwigshafen, Germany) under the IRGACURE™ brand. A wide variety of binder polymers may be used, such as to provide improved coating quality or leveling over the substrate, particularly when the matrix precursor material is an organometallic material. Suitable binder polymers are disclosed in U.S. patent application Ser. No. 13/776,496.

The present coating compositions may be prepared by combining the matrix precursor material, the oxymetal precursor material, organic solvent, and any optional additives in any order. It will be appreciated by those skilled in the art that the concentration of the components in the present compositions may be varied across a wide range. Preferably, the matrix precursor material is present in the composition in an amount of from 2 to 20 wt %, preferably from 4 to 15 wt %, and more preferably from 6 to 10 wt %, based on the total weight of the coating composition. Preferably, the oxymetal precursor material is present in the composition in an amount of from 3 to 15 wt %, more preferably from 5 to 10 wt %, and yet more preferably from 5 to 8 wt %, relative to the solid content of the matrix precursor material. It will be appreciated by those skilled in the art that higher or lower amounts of such components may be used in the present coating compositions.

In use, the present coating compositions are disposed on an electronic device substrate. A wide variety of electronic device substrates may be used in the present invention, such as: packaging substrates such as multichip modules; flat panel display substrates; integrated circuit substrates; substrates for light emitting diodes (LEDs) including organic light emitting diodes (OLEDs); semiconductor wafers; polycrystalline silicon substrates; and the like. Such substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, gold, glass, organic or inorganic coated glass. Suitable substrates may be in the form of wafers such as those used in the manufacture of integrated circuits, optical sensors, flat panel displays, integrated optical circuits, and LEDs. As used herein, the term “semiconductor wafer” is intended to encompass “an electronic device substrate,” “a semiconductor substrate,” “a semiconductor device,” and various packages for various levels of interconnection, including a single-chip wafer, multiple-chip wafer, packages for various levels, or other assemblies requiring solder connections. Particularly suitable substrates are those comprising LEDs, including OLEDs. Such substrates may be any suitable size. Preferred wafer substrate diameters are 200 mm to 300 mm, although wafers having smaller and larger diameters may be suitably employed according to the present invention. As used herein, the term “semiconductive substrates” includes any substrate having one or more semiconductor layers or structures which include active or operable portions of semiconductor devices. The term “semiconductor substrate” is defined to mean any construction comprising semiconductive material, including but not limited to bulk semiconductive material such as a semiconductive wafer, either alone or in assemblies comprising other materials thereon, and semiconductive material layers, either alone or in assemblies comprising other materials. A semiconductor device refers to a semiconductor substrate upon which at least one microelectronic device has been or is being batch fabricated. Preferred substrates are substrates for LEDs, and more preferably for OLEDs. Also preferred are flexible display substrates and photovoltaic device substrates, and more preferred are flexible display substrates for LEDs, and more preferably for OLEDs.

The present coating compositions may be disposed on an electronic device substrate by any suitable means, such as spin-coating, slot-die coating, doctor blading, curtain coating, roller coating, spray coating, dip coating, and the like. Spin-coating and slot-die coating are preferred. In a typical spin-coating method, the present compositions are applied to a substrate which is spinning at a rate of 500 to 4000 rpm for a period of 15 to 90 seconds to obtain a desired layer of the matrix precursor material and the oxymetal precursor material. It will be appreciated by those skilled in the art that the total height of the layers may be adjusted by changing the spin speed, as well as the percentage solids in the composition.

While not wishing to be bound by theory, it is believed that the oxymetal precursor material migrates toward the surface of the forming film during deposition of the present compositions and during any subsequent solvent removal step. It is believed that the relatively low surface energy of the oxymetal precursor material helps drive the oxymetal precursor material to the air interface. As a result, a multilayer structure is obtained where a layer of the oxymetal precursor material is disposed on a layer of the matrix precursor material. While some intermixing of the layers may be present, the top portion of the structure will be comprised of a majority of the oxymetal precursor material while the bottom portion will be comprised of a majority of the matrix precursor material. It will be appreciated by those skilled in the art that such migration of the oxymetal precursor material should substantially occur before the complete curing of the matrix precursor material. The formation of a cured matrix material film substantially prohibits migration of the oxymetal precursor material.

During or after the deposition of the present coating compositions on an electronic device substrate to form a multilayer structure (oxymetal precursor material layer on a matrix precursor material layer), the structure is optionally baked at a relatively low temperature to remove any remaining solvent and other relatively volatile components. Typically, the substrate is baked at a temperature of ≦125° C., preferably from 60 to 125° C., and more preferably from 90 to 115° C. The baking time is typically from 10 seconds to 10 minutes, preferably from 30 seconds to 5 minutes, and more preferably from 6 to 180 seconds. When the substrate is a wafer, such baking step may be performed by heating the wafer on a hot plate.

Following any baking step to remove solvent, the multilayer structure layer is cured, such as in an oxygen-containing atmosphere, such as air, or in an inert environment, such as in nitrogen. The curing step is conducted preferably on a hot plate-style apparatus, though oven curing may be used to obtain equivalent results. Typically, such curing is performed by heating the multilayer structure at a curing temperature of ≧150° C., and preferably 150 to 400° C. It is more preferred that the curing temperature is ≧200 to 400° C., still more preferably ≧250 to 400° C., and even more preferably from 250 to 400° C. The choice of final curing temperature depends mainly upon the desired curing rate, with higher curing temperatures requiring shorter curing times. When the present oxymetal precursor material layers are cured at temperatures ≧200° C., the resulting oxymetal domain-containing films are resistant to stripping (being removed) by solvents conventionally used in the application of antireflective coatings and photoresists. When the present oxymetal precursor materials are cured at temperatures ≧350° C., the resulting oxymetal domain-containing films are also resistant to stripping by alkaline or solvent developers conventionally used in the development of imaged photoresist layers. Typically, the curing time may be from 10 seconds to 30 minutes, preferably from 30 seconds to 30 minutes, more preferably from 45 seconds to 30 minutes. During the curing step, at least a portion of the matrix precursor material forms a cured matrix material and at least a portion of the oxymetal precursor material cures to form a layer containing oxymetal domains having an (—M—O—)ₙ linkage, where n>100. Typically, the amount of the metal in the cured oxymetal domain-containing films may be up to 95 mol % (or even higher), and preferably from 50 to 95 mol %. It will be appreciated by those skilled in the art that the cured oxymetal material layer may contain, in addition to oxy-metal domains, other domains, such as metal nitride domains, as well as optionally containing carbon, such as an amount of up to 5 mol % carbon.

The initial baking step may not be necessary if the final curing step is conducted in such a way that rapid evolution of the solvents and curing by-products is not allowed to disrupt the film quality. For example, a ramped bake beginning at relatively low temperatures and then gradually increasing to the range of 250 to 400° C. can give acceptable results. It can be preferable in some cases to have a two-stage curing process, with the first stage being a lower bake temperature of less than 250° C., and the second stage being a higher bake temperature preferably between 250 and 400° C. Two stage curing processes facilitate uniform filling and planarization of pre-existing substrate surface topography.

While not wishing to be bound by theory, it is believed that the conversion of the oxymetal precursor material to an oxymetal domain-containing film involves hydrolysis by moisture that is contained in the coating and/or adsorbed from the atmosphere during the deposition (casting) and curing processes. Therefore, the curing process is preferably carried out in air or in an atmosphere where moisture is present to facilitate complete conversion to the oxymetal precursor material to an oxymetal domain-containing film. However, when a polymeric matrix precursor material is used, it is preferred to cure the matrix precursor material under inert atmosphere, such as N₂, in order to reduce the possibility of degradation of the polymeric material. The curing process can also be aided by exposure of the coating to ultraviolet radiation, preferably in a wavelength range of from about 200 to 400 nm. The exposure process can be applied separately or in conjunction with a thermal curing process.

Optionally, a second layer of the present coating composition may be disposed on the cured oxymetal material layer, and treated as described above. This results in a cured structure having an alternating layer structure of cured matrix material-oxymetal material-matrix material-oxymetal material. This process may be repeated any number of times to build a stack of such alternating layers.

Depending on the particular application, the present cured oxymetal material layer may be subjected to further processing steps, such as patterning. Such further processing steps may require the application of one or more organic materials, such as photoresists and antireflective coatings, to the surface of the oxymetal material layer. Cured oxymetal material layers typically have a surface energy that is very different from that of subsequently applied organic layers. Such a mismatch of surface energy causes poor adhesion between the oxymetal material layer and the subsequently applied organic layer. In the case of a subsequently applied photoresist layer, such mismatch in surface energy results in severe pattern collapse. In order to make the surface of the present oxymetal material films more compatible with subsequently applied organic layers, the surface may optionally be treated with an appropriate surface treating agent.

Surface treating compositions useful for treating the surface of the cured oxymetal material films are those disclosed in U.S. patent application Ser. No. 13/745,752 and comprise an organic solvent and a surface treating agent, where the surface treating agent comprises one or more surface treating moieties. Optionally, the surface treating composition may further comprise one or more additives, such as thermal acid generators, photoacid generators, antioxidants, dyes, contrast agents, and the like. A wide variety of organic solvents may suitably be used, such as, but are not limited to, aromatic hydrocarbons, aliphatic hydrocarbons, alcohols, lactones, esters, glycols, glycol ethers, and mixtures thereof. Exemplary organic solvents include, without limitation, toluene, xylene, mesitylene, alkylnaphthalenes, 2-methyl-1-butanol, 4-methyl-2-pentanol, gamma-butyrolactone, ethyl lactate, 2-hydroxyisobutyric acid methyl ester, propylene glycol methyl ether acetate, and propylene glycol methyl ether. Suitable solvents have a relatively higher vapor pressure than the surface treating agent, such that the solvent may be removed from the surface of the film leaving behind the surface treating agent. It is preferred that the organic solvents do not have free carboxylic acid groups or sulfonic acid groups. A wide variety of surface treating agents may be used in the surface treating compositions and may be polymeric or non-polymeric, and comprise one or more surface treating moieties. Exemplary surface treating moieties include hydroxyl (—OH), thiol (—SH), carboxyl (—CO₂H), betadiketo (—C(O)—CH₂—C(O)—), protected carboxyl, and protected hydroxyl groups. While amino groups will work, it is preferred that the surface treating agents are free of amino groups, and preferably free of nitrogen, as such groups may adversely affect the function of subsequently applied coatings such as chemically amplified photoresists. Protected carboxyl groups and protected hydroxyl groups are any groups which are cleavable under certain conditions to yield a carboxyl group or hydroxyl group, respectively. Such protected carboxyl groups and protected hydroxyl groups are well-known in the art. When the surface treating agent comprises one or more protected hydroxyl groups, it is preferred that a thermal acid generator (TAG) or a photoacid generator (PAG) be used in the surface treating composition.

As surface energy is often difficult to measure, surrogate measurements, such as water contact angles, are typically used. The determination of water contact angles is well-known, and a preferred method uses using a Kruss drop shape analyzer Model 100, using deionized (“DI”) water and a 2.5 μL drop size. Cured oxymetal material layers typically have a water contact angle of ≦50°, such as from 35 to 45°. Following treatment with a surface treating composition, the oxymetal material film surface typically has a water contact angle of ≧55°, such as from 55 to 70°. Following treatment with the surface treating agent, the oxymetal material film surface has a surface energy that substantially matches that of a subsequently applied organic layer, that is, the surface energy of the treated hardmask layer should be within 20% of the surface energy of a subsequently applied organic layer. Subsequent processing steps involving organic layers applied over the oxymetal material layer will have fewer defects as compared to oxymetal material films without such surface treatment.

The present cured matrix materials and oxymetal materials may suitably function as hardmask layers, dielectric layers, barrier layers, and the like. A preferred barrier layer structure prepared according to the present invention comprises a layer of a silicon oxide matrix material having layer of titanium oxide or aluminum oxide (the oxymetal material layer) disposed on the surface of the silicon oxide layer. Such barrier layer structures are particularly suitable for use as an oxygen barrier in the manufacture of LEDs, and preferably in the manufacture of OLEDs.

### EXAMPLE 1

### Alumoxane Materials

12.0 g of aluminum tris-isopropoxide (or Al(Oi-Pr)₃) was mixed with 150.0 g of ethyl lactate in a 250 mL round bottom flask equipped with a magnetic stir bar and connected to a condenser and a thermocouple. With adequate stirring, the mixture in the flask was heated by way of a heating mantle which was controlled through the thermocouple. The mixture was heated to reflux temperature and maintained at reflux for 2 hours. Heating was then stopped and the mixture was allowed to cool naturally to room temperature with stirring. This ligand exchange reaction in excess ethyl lactate provided tris((1-ethoxy-1-oxopropan-2-yl)oxy)aluminum. Next, 0.90 g of DI water and 60.0 g of ethyl lactate were mixed and this aqueous solvent mixture was fed to the reactor over a period of ca. 13 minutes with stirring. The reaction mixture was then again heated to reflux and held at reflux for 2 hours, after which time heating was stopped and the reaction mixture was allowed to cool naturally to room temperature to provide an alumoxane trimer having 5 ligands derived from ethyl lactate. The reaction mixture was then filtered through a 1.0 μm perfluoropolyethylene (PFPE) filter to remove any insoluble materials, and then filtered through a 0.2 μm PFPE filter. The filtered solution was found to contain 6.2% solids using a weight loss method in a thermal oven.

Weight Loss Method:

Approximately 0.1 g of the organoaluminum compound in solution was weighed into a tared aluminum pan. Approximately 0.5 g of the solvent used to form the organoaluminum compound (ethyl lactate) was added to the aluminum pan to dilute the test solution to make it cover the aluminum pan more evenly. The aluminum pan was heated in a thermal oven at approximately 110° C. for 15 minutes. After the aluminum pan cooled to room temperature, the weight of the aluminum pan with dried solid film was determined, and the percentage solid content was calculated.

### EXAMPLE 2

50.0 g of the alumoxane solution from Example 1 was weighed into a 100 mL round bottom flask with stirring. Octanoic acid (0.9696 g, ca. 3 eq. molar amount based on the number of ligands) was added to the flask. The reaction was carried out at 60° C. for 3 hours with adequate stirring provided by a magnetic stirring bar to provide an alumoxane trimer having 2 ligands derived from ethyl lactate and 3 ligands derived from octanoic acid as a product. The reaction mixture changed from clear to cloudy, the cloudiness being indicative that the new compound containing octanoate ligands began to lose its solubility in ethyl lactate, which is too polar a solvent.

### EXAMPLE 3

One part of the solution from Example 2 was mixed with 3 parts of toluene to provide a clear solution. The solution was then filtered through a 1.0 μm PFPE filter once and through a 0.2 μm PFPE filter 3 times before being processed. The process included spin coating the filtered solution at 500 rpm on a bare silicon wafer followed by baking the coated film at 100° C. for 60 seconds. The film was then measured for surface water contact angle using a KRUSS drop shape analyzer (DSA) 100 with 2.5 μL DI water droplet size. The contact angle of this alumoxane film was found to be 82.6° whereas a film prepared from the aluminum material from Example 1 had a water contact angle of 25.2°.

### EXAMPLE 4

### Titanium Materials

Into a 100 mL round bottom flask equipped with a magnetic stir bar were weighed 4.365 g of an oligomeric butyl titanate (4.95 mmoles, assuming average chain length of 4 titanium atoms) (available from Dorf Ketal under the TYZOR BTP brand) and 30.0 g of propylene glycol methyl ether acetate (PGMEA). The mixture was stirred to ensure a uniform solution before adding 7.260 g (50.3 mmoles) of octanoic acid to the flask. With continuous stirring, the temperature of the reactant mixture was brought to 80° C. and held at 80° C. for 2.5 hours. Then the heating was stopped and the reaction mixture was allowed to cool naturally to room temperature, and the solution was used as is. Following the weight loss procedure of Example 1, the solution was found to contain 12.06% solids of an oligomeric octanoyl titanate.

### EXAMPLE 5

A sample (4.453 g) of the solution from Example 4 was diluted by mixing it with 2.420 g of PGMEA. The diluted solution was then filtered through a 0.2 μm PFPE filter 4 times before being processed. The filtered sample was spin coated at 1500 rpm on a bare silicon wafer. The spin coated film was then baked at 100° C. for 60 seconds. The water contact angle of this film was found to be 97.9° using a KRUSS drop shape analyzer (DSA) 100 with a 2.5 μL water drop size. A control wafer was prepared by spin coating a film of an oligomeric butyl titanate (TYZOR BTP in PGMEA and having a similar solids content to the solution in Example 4), and then processing this control film under the same conditions as the film as the film in this example. The water contact angle of this control film was found to be 49°.

### EXAMPLE 6

Coating composition samples were prepared as follows. A stock solution of a B-staged polyphenylene matrix precursor material (SiLK™ D resin, available from The Dow Chemical Company) was diluted with PGMEA to provide a 4 wt % solution. 5.0 g of this stock matrix precursor solution were added to each of Samples A-D. Various amounts of the oxymetal precursor material from Example 4 were also added to each of Samples B-D, as shown in Table 1. Sample A, which contained no oxymetal precursor material, was used as a control. The relative amounts of the oxymetal precursor material from Example 4 as compared to the amount of the matrix precursor material, on a solids basis, are also reported in Table 1. An amount of a cosolvent, gamma-butyrolactone (GBL), was also added to each of Samples A-D, as shown in Table 1. Each sample was filtered through a 0.2 μm PFPE syringe filter 4 times before being spin coated at 1500 rpm on a bare silicon wafer and then baked at 100° C. for 60 seconds. The water contact angles of these coated films were measured using a KRUSS drop shape analyzer (DSA) 100 with 2.5 μL DI water droplet size and are reported in Table 1.

TABLE 1

| | | | Relative Solid | Water |
|---|---|---|---|---|
| | Solution from | | Content of | Contact |
| Sample | Example 4 | GBL | Oxymetal Precursor | Angle |
| A (Control) | 0 | 0.261 g | 0 | 83° |
| B | 0.087 g | 0.254 g | 5% | 90° |
| C | 0.166 g | 0.260 g | 10% | 95° |
| D | 0.251 g | 0.259 g | 15% | 95° |

As seen from the data in Table 1, the cured matrix material (Control Sample) itself is hydrophobic (low in surface energy) as indicated by its high water contact angle of 83°. However, as the data in Table 1 show, the oxymetal precursor material from Example 4 is still able to come to the topmost surface to increase the water contact angle value relative to the Control.

The wafer containing the film from Sample B was then cleaved into coupons, one of which was cured at 380° C. for 30 minutes under nitrogen atmosphere in a belt furnace. This cured coupon along, with an coupon containing an uncured film of Sample B, was then subjected to a positive SIMS analysis to determine element distribution across the film thickness. Both the cured and uncured films clearly showed a high concentration of titanium at the surface, quickly dropping to an insignificant level of titanium within the bulk of the film. This clearly shows that the oxymetal precursor material concentrates at the surface, resulting in a structure having a layer of oxymetal material on a layer of matrix material.

### EXAMPLE 7

The procedure of Example 5 was repeated except that the polyphenylene matrix precursor material was replaced with a silicon-containing matrix precursor material. A silsesquioxane oligomer of methyl trimethoxysilane/phenyl trimethoxysilane/tetraethyl orthosilicate (25/50/25 mole ratio) having a weight average molecular weight of 4205 and a number average molecular weight of 2117, was prepared using known procedures. This silsesquioxane oligomer material was first diluted with PGMEA to form a 4.0% solution. Five grams of the silsesquioxane matrix precursor material were added to each of Samples E-H. Sample E served as the control, and contained no oxymetal precursor material. An amount of the oxymetal precursor material from Example 4 was added to each of Samples F—H, as shown in Table 2. Cosolvent (GBL) was also added to each of the Samples. Each of the samples was filtered, spin coated on a bare silicon wafer, and baked, followed by determination of the water contact angles of these films, as described in Example 5. The results are reported in Table 2.

TABLE 2

| | | | Relative Solid | Water |
|---|---|---|---|---|
| | Solution from | | Content of | Contact |
| Sample | Example 4 | GBL | Oxymetal Precursor | Angle |
| E (Control) | 0 | 0.2516 g | 0 | 74.5° |
| F | 0.0846 g | 0.2513 g | 5% | 81.9° |
| G | 0.1665 g | 0.2625 g | 10% | 88.8° |
| H | 0.2497 g | 0.2663 g | 15% | 89.0° |

The difference in water contact angles between Control Sample E and Samples F—H clearly shows that the oxymetal precursor material, having a low surface energy, has migrated to the film surface during the coating process.

The coated films in this example were then subjected to a curing at 380° C. for 30 minutes. The cured films were then measured for surface roughness using AFM (atomic force microscopy) with a 2×2 μm scan area and 1.5 Hz scan rate. Lower surface roughness values indicate a smoother surface. As can be seen from the data reported in Table 3, Samples F and H that contained the oxymetal precursor material provided smoother films than Control Sample E without the oxymetal precursor material.

TABLE 3

| Sample | Ra | Rs | Z |
|---|---|---|---|
| E (Control) | 0.5 nm | 0.6 nm | 4.9 nm |
| F | 0.4 nm | 0.4 nm | 3.6 nm |
| H | 0.3 nm | 0.4 nm | 3.0 nm |

### EXAMPLE 8

A silsesquioxane oligomer of tetraethyl orthosilicate/phenyl trimethoxysilane/vinyl trimethoxysilane/methyl trimethoxysilane (50/9/15/26 mole ratio) was prepared using known procedures. This silsesquioxane matrix precursor material was provided as a solution in a mixed solvent system of PGMEA/ethyl lactate (95/5 w/w) having 2.18% solids content. A coating composition was prepared by combining 5 g of this silsesquioxane matrix precursor material solution with 0.135 g of the oxymetal precursor material solution from Example 4 and 0.247 g of GBL. This coating composition sample was then filtered through a 0.2 μm PFPE syringe filter 4 times before being spin coated at 1500 rpm on a bare silicon wafer, followed by baking the coated film at 100° C. for 60 seconds. The coated wafer was then cleaved into coupons, one of which was cured at 380° C. for 30 minutes. This cured coupon along with an coupon having an uncured film deposited from the same coating composition were then subjected to a positive SIMS analysis using a conventional instrument and process conditions to determine metal (titanium) distribution throughout the film thickness. The SIMS data clearly showed that titanium is primarily distributed on the topmost surface of both the cured and uncured films.

### EXAMPLE 9

Sample H from Example 7 was spin coated on a bare silicon wafer at 1500 rpm and the coated film was baked at 350° C. for 120 seconds to cure the film. This wafer was then coated with the same sample again using the identical processed conditions. This two-coating stack was then analyzed for titanium distribution throughout the film thickness using a SIMS with a positive ion mode. The SIMS analysis showed two local titanium maxima. One maximum was at the air-solid interface, and the second maximum was at the interface between the two coating compositions, where it was the topmost layer of the first coating composition deposition.

### EXAMPLE 10

The procedure of Example 4 was repeated except that 4.242 g of oligomeric butyl titanate (TYZOR BTP, assuming average chain length of 4 titanium atoms) and 15.01 g of PGMEA were weighed into a 100 mL round bottom flask equipped with a magnetic stir bar and a condenser. This stirred mixture was heated to 80° C. before a solution of octanoic acid (6.339 g) in PGMEA (15.03 g) solution was fed into the stirred reaction mixture over a period of 3.3 minutes. After the octanoic acid solution was fed into the flask, the reaction mixture was maintained at 80° C. for 2 hours, and was then cooled naturally to room temperature. Based on the stoichiometry, 91% of the butoxide ligands in the starting titanium material were replaced with octanoic acid ligands. The reaction solution was used as is without further purification. This solution was found to have a solids content of 11.20%, according to the weight loss method of Example 1.

### EXAMPLE 11

The procedure of Example 10 was repeated except that 4.301 g of oligomeric butyl titanate and 15.02 g of PGMEA were used. The octanoic acid/PGMEA solution was prepared by combining 6.115 g of octanoic acid and 15.03 g of PGMEA, and was fed into the stirred reaction mixture over a period of 2.0 minutes. Based on the stoichiometry, 85% of the butoxide ligands in the starting titanium material were replaced with octanoic acid ligands. The reaction solution was used as is without further purification. This solution was found to have a solids content of 11.76%, according to the weight loss method of Example 1.

### EXAMPLE 12

Two coating compositions, Samples I and J, were prepared using 10 g of the silsesquioxane matrix precursor material from Example 7, and either the oxymetal precursor material of Example 10 or Example 11 as well as GBL as a cosolvent, in the amounts shown in Table 4. The relative amount of the oxymetal precursor material as compared to the amount of the silsesquioxane matrix precursor material, on a solids basis, for each of Samples I and J was 15%.

TABLE 4

| | | | Water |
|---|---|---|---|
| | Oxymetal Precursor | | Contact |
| Sample | Material | GBL | Angle |
| I | 0.5335 g | 0.5045 g | 90.6° |
| | (Example 10) | | |
| J | 0.5164 g | 0.5090 g | 90.3° |
| | (Example 11) | | |

Each of the samples was then filtered through a 0.2 μm PFPE syringe filter 4 times before being spin coated at 1500 rpm on bare silicon wafers, followed by baking at 100° C. for 60 seconds. Water contact angles of these films were measured using a KRUSS drop shape analyzer (DSA) 100 with DI water drop size of 2.5 μL, and the results are reported in Table 4. The water contact angles for these films are similar to the water contact angles obtained in Example 6, indicating that not all of the ligands on the oxymetal precursor material need to be low surface energy ligands in order for the oxymetal precursor material to have a sufficiently low surface energy to migrate to the top region of the coating.

### EXAMPLE 13

### Hafnium Materials

Into a 100 mL round bottom flask equipped with a magnetic stir bar were weighed 10.0 g of ethyl lactate and 5.289 g hafnium tetrabutoxide (available from TCI America). To this stirred mixture was then added dropwise a solution of 0.1219 g DI water and 5.1308 g ethyl lactate. The mixture was then heated to reflux and maintained at reflux for 2 hours with stirring, and was then cooled naturally to room temperature. A solution of 2.682 g of 2-naphthoic acid, 3.3748 g of octanoic acid and 8.047 g of ethyl lactate was then added dropwise to the mixture with stirring. The mixture was then heated with stirring to 60° C. and maintained at 60° C. temperature for 2 hours, and was then cooled naturally to room temperature. Following the weight loss procedure of Example 1, the solution was found to contain 17.5% solids of an oligomeric octanoyl/naphthoyl hafnate.

### EXAMPLE 14

### Preparation of Hf(OBu)acetyl-diethylene glycol copolymer

A 500 mL three-necked flask was equipped with a reflux condenser, a mechanical stirrer and an addition funnel. To this reactor was added 100 g (0.21 mol) of Hf(OBu)₄ (available from Gelest Inc.). To this vigorously stirred material was added pentane-2,4-dione (42.5 g, 0.42 mol) very slowly over 6 hours. The reaction mixture was stirred overnight at room temperature. n-Butanol produced during the reaction was removed under vacuum and then 800 mL of ethyl acetate was added and the reaction flask was stirred vigorously at room temperature for 30 minutes. This solution was filtered through a fine frit to remove any insoluble products. Remaining solvent was removed under vacuum and a pale white solid was obtained (100.4 g, 90% yield). This product, Hf(OBu)₂(acac)₂, was used without further purification.

To a 1 L three-necked flask equipped with a reflux condenser, a stirring bar and a thermal meter was added an ethyl acetate (500 mL) solution of the above product (100.4 g, 0.19 mol) and ethylene diglycol (19.4 g, 0.18 mol). The reaction mixture was refluxed at 80° C. for 24 hours. The reaction mixture was filtered through a fine frit and then dried under vacuum. The brown-white solid was washed with heptane (3×1 L) and then dried under strong vacuum for 2 hours, yielding the desired Hf(OBu)acetyl-diethylene glycol copolymer as a white powder (67 g). The product obtained had the following structure.

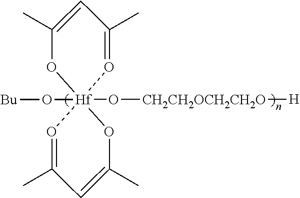

### EXAMPLE 15

A coating composition is prepared using the Hf(OBu)acetyl-diethylene glycol copolymer of Example 14 as the organometallic matrix precursor material. A solution of the Hf(OBu)acetyl-diethylene glycol copolymer in 2-methyl-1-butanol (6% solids) is prepared. To this solution is added an amount of the oxymetal (titanate) precursor solution of Example 11. The relative amount of the oxymetal (titanate) precursor material from Example 11 as compared to the amount of the organometallic matrix precursor material, on a solids basis, is 5%. An amount of GBL cosolvent (5 vol %) is also added to the composition. The composition is filtered through a 0.2 μm PFPE syringe filter 4 times before being spin coated at 1500 rpm on a bare silicon wafer. Next, the wafer is baked at 100° C. for 60 seconds, and is then cured at 380° C. for 2 minutes, to provide a layer of a cured hafnium oxide matrix material and a layer of titanium oxide material on the hafnium oxide layer.

### EXAMPLE 16

### Preparation of Zr(OBu)acetyl-diethylene glycol copolymer

Zirconium bis(acetylacetone)-bis(n-butoxide) (or Zr(acac)₂(OBu)₂), 25 wt % in toluene/butanol, was obtained from Gelest Inc. and used without further purification. The solvent was removed from 200 g of Zr(acac)₂(OBu)₂, and the residue was diluted with 250 mL ethyl acetate. To this mixture was added an equimolar amount of diethyleneglycol at room temperature and then the mixture was refluxed at 80° C. for 18 hr. Next, the reaction mixture was cooled and filtered to remove a white precipitate. The filtrate was concentrated to a small volume using a rotary evaporator and the residue quenched in heptane. The precipitate was then collected and dried in vacuum to give 20.8 g of the desired product, whose structure is shown below.

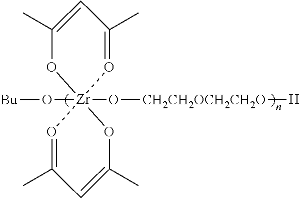

### EXAMPLE 17

A coating composition is prepared using the Zr(OBu)acetyl-diethylene glycol copolymer of Example 16 as the organometallic matrix precursor material. A solution of the Zr(OBu)acetyl-diethylene glycol copolymer in 2-methyl-1-butanol (6% solids) is prepared. To this solution is added an amount of the oxymetal (titanate) precursor solution of Example 11. The relative amount of the oxymetal (titanate) precursor material from Example 11 as compared to the amount of the organometallic matrix precursor material, on a solids basis, is 5%. An amount of GBL cosolvent (5 vol %) is also added to the composition. The composition is filtered through a 0.2 μm PFPE syringe filter 4 times before being spin coated at 1500 rpm on a bare silicon wafer. Next, the wafer is baked at 100° C. for 60 seconds, and is then cured at 380° C. for 2 minutes, to provide a layer of a cured zirconium oxide matrix material and a layer of titanium oxide material on the zirconium oxide layer.

What is claimed is:

1. A method of forming an oxymetal layer on a matrix layer on an electronic device substrate comprising: disposing a layer of a coating composition on an electronic device substrate, wherein the coating composition comprises a matrix precursor material, an oxymetal precursor material having a surface energy of 20 to 40 erg/cm², and an organic solvent; subjecting the coating composition layer to conditions such that a layer of the oxymetal precursor material forms on a layer of the matrix precursor material; and curing the layer of matrix precursor material and the layer of oxymetal precursor material.

2. The method of claim 1 wherein the organic solvent comprises a first organic solvent and a second organic solvent.

3. The method of claim 1 wherein the oxymetal precursor material comprises a metal selected from Group 3 to Group 14.

4. The method of claim 3 wherein the metal is selected from the group consisting of titanium, zirconium, hafnium, tungsten, tantalum, molybdenum, and aluminum.

5. The method of claim 1 wherein the matrix precursor material comprises a silicon-containing material.

6. The method of claim 1 wherein the matrix precursor material has a surface energy that is higher than the surface energy of the oxymetal precursor material.

7. The method of claim 6 wherein the matrix precursor material has a surface energy that is ≧10 ergs/cm² higher than the surface energy of the oxymetal precursor material.

8. The method of claim 1 wherein the matrix precursor material layer and the oxymetal precursor material layer are cured by heating.

9. The method of claim 1 wherein the substrate is a substrate for light emitting diodes.

10. The method of claim 1 further comprising disposing a second layer of the coating composition on the surface of the cured oxymetal layer and subjecting the second coating composition layer to conditions such that a second layer of the oxymetal precursor material forms on a second layer of the matrix precursor material; and curing the second layer of matrix precursor material and the second layer of oxymetal precursor material.

11. A composition comprising a matrix precursor material, an oxymetal precursor material having a surface energy of 20 to 40 erg/cm², and an organic solvent, wherein the matrix precursor material has a surface energy that is higher than the surface energy of the oxymetal precursor material.
